(19) United States
(12) Patent Application Publication
(10) Pub. No.: US 2024/0268167 A1
(43) Pub. Date: Aug. 8, 2024

(54) DISPLAY PANEL AND DISPLAY APPARATUS

(71) Applicant: Samsung Display Co., Ltd., Yongin-Si (KR)

(72) Inventors: Kyungmin Kim, Yongin-si (KR); Taehyun KIM, Yongin-si (KR); Myunghee Han, Yongin-si (KR)

(21) Appl. No.: 18/432,732

(22) Filed: Feb. 5, 2024

(30) Foreign Application Priority Data
Feb. 6, 2023 (KR) 10-2023-0015721

(51) Int. Cl. H10K 59/131

(52) U.S. Cl. CPC H10K 59/131

(57) ABSTRACT

A display panel and a display apparatus are disclosed. The display panel includes: a substrate including a front display area, a first corner display area extending from a corner of the front display area, and a second corner display area extending from the first corner display area; a plurality of corner light-emitting elements arranged in the second corner display area; a plurality of pixel circuits arranged in the first corner display area; driving circuits arranged in the second corner display area and configured to provide driving signals to the plurality of pixel circuits; and a plurality of connection wirings connecting the plurality of pixel circuits and the plurality of corner light-emitting elements to each other and extending from the first corner display area to the second corner display area, wherein the plurality of connection wirings include first connection wirings disposed on a first layer and second connection wirings disposed on a second layer, and one of the plurality of pixel circuits is connected to at least two of the plurality of corner light-emitting elements.

### CROSS-REFERENCE TO RELATED APPLICATION

This application is based on and claims priority under 35 U.S.C. §119 to Korean Patent Application No. 10-2023-0015721, filed on Feb. 6, 2023, in the Korean Intellectual Property Office, the disclosure of which is incorporated by reference herein in its entirety.

### BACKGROUND

### 1. Field

The present disclosure relates to a display panel and a display apparatus including the same, and more particularly, to a display panel in which a display area may be expanded so that an image may be displayed even in corner areas, and a display apparatus including the display panel.

### 2. Description of the Related Art

Recently, designs of display apparatuses have been diversifying. For example, curved display apparatuses, foldable display apparatuses, and rollable display apparatuses are being developed. In addition, display areas are expanding, and non-display areas are shrinking. Thus, various methods have been developed to design the shape of the display apparatus.

### SUMMARY

One or more embodiments provide a display panel in which a display area may be expanded so that an image may be displayed even in corner areas, and a display apparatus including the display panel. However, this objective is illustrative, and the scope of the disclosure is not limited thereby.

Additional aspects will be set forth in part in the description which follows and, in part, will be apparent from the description, or may be learned by practice of the presented embodiments of the disclosure.

According to an embodiment of the disclosure, a display panel includes a substrate including a front display area, a first corner display area extending from a corner of the front display area, and a second corner display area extending from the first corner display area, a plurality of corner light-emitting elements arranged in the second corner display area, a plurality of pixel circuits arranged in the first corner display area, driving circuits arranged in the second corner display area and configured to provide driving signals to the plurality of pixel circuits, and a plurality of connection wirings connecting the plurality of pixel circuits and the plurality of corner light-emitting elements to each other and extending from the first corner display area to the second corner display area, wherein the plurality of connection wirings include first connection wirings disposed on a first layer and second connection wirings disposed on a second layer, and one of the plurality of pixel circuits is connected to at least two of the plurality of corner light-emitting elements.

The plurality of corner light-emitting elements may include a plurality of first light-emitting elements configured to emit light of a first color, a plurality of second light-emitting elements configured to emit light of a second color, and a plurality of third light-emitting elements configured to emit light of a third color, wherein at least two of the plurality of second light-emitting elements may share a pixel electrode of the at least two of the plurality of second light-emitting elements, and at least two of the plurality of third light-emitting elements may share a pixel electrode of the at least two of the plurality of third light-emitting elements.

At least two of the first light-emitting elements may be connected to each other by a bridge wiring disposed on the first layer or the second layer.

In one of the plurality of connection wirings, a (1-1)-connection wiring disposed on the first layer and a (2-1)-th connection wiring disposed on the second layer may be connected to each other through a contact hole.

One of the plurality of connection wirings may include a (1-2)-th connection wiring disposed on the first layer and a (2-2)-th connection wiring disposed on the second layer, and the (2-2)-th connection wiring may be connected to the (1-2)-th connection wiring through a first contact hole and may be connected to the (1-3)-th connection wiring through a second contact hole.

One of the plurality of connection wirings may include a (1-4)-th connection wiring disposed on the first layer, and one end of the (1-4)-th connection wiring may be connected to one of the plurality of pixel circuits, and the other end of the (1-4)-th connection wiring may be connected to a pixel electrode of one of the plurality of corner light-emitting elements through a contact hole.

One of the plurality of connection wirings may include a (2-3)-th connection wiring disposed on the second layer, and one end of the (2-3)-th connection wiring may be connected to one of the plurality of pixel circuits, and the other end of the (2-3)-th connection wiring may be connected to a pixel electrode of one of the plurality of corner light-emitting elements through a contact hole.

The first connection wirings and the second connection wirings may include transparent conductive materials.

The substrate may further include a component area inside the front display area and including a transmission area, and a transition area between the component area and the front display area, and the display panel may further include auxiliary light-emitting elements arranged in the component area, auxiliary pixel circuits arranged in the transition area and configured to drive the auxiliary light-emitting elements, and a plurality of transparent connection wirings configured to connect the auxiliary pixel circuits to the auxiliary light-emitting elements, and the plurality of transparent connection wirings may include a first transparent connection wiring disposed on the first layer and a second transparent connection wiring disposed on the second layer.

The display panel may further include an inorganic insulating layer disposed on the substrate, and the inorganic insulating layer may have a groove corresponding to the component area.

According to an embodiment of the disclosure, a display apparatus includes a cover window including a flat surface portion (a planar portion) and a curved surface portion (a curved portion) bent at a corner of the flat surface portion, and a display panel including a front display area overlapping the flat surface portion, a first corner display area and a second corner display area, which overlap the curved surface portion, wherein the display panel may further include a plurality of pixel circuits arranged in the first corner display area, a plurality of corner light-emitting elements arranged in the second corner display area, and a plurality of connection wirings connecting the plurality of pixel circuits and the plurality of corner light-emitting elements to each other and extending from the first corner display area to the second corner display area, and the plurality of connection wirings may include first connection wirings disposed on a first layer and second connection wirings disposed on a second layer, and one of the plurality of pixel circuits may be connected to at least two of the plurality of corner light-emitting elements.

At least two of the plurality of corner light-emitting elements may share a pixel electrode of the at least two of the plurality of corner light-emitting elements.

In one of the plurality of connection wirings, a (1-1)-th connection wiring disposed on the first layer and a (2-1)-th connection wiring disposed on the second layer may be connected to each other through a contact hole.

One of the plurality of connection wirings may include a (1-2)-th connection wiring disposed on the first layer and a (2-2)-th connection wiring disposed on the second layer, and the (2-2)-th connection wiring may be connected to the (1-2)-th connection wiring through a first contact hole and may be connected to the (1-3)-th connection wiring through a second contact hole.

One of the plurality of connection wirings may include a (1-4)-th connection wiring disposed on the first layer, and one end of the (1-4)-th connection wiring may be connected to one of the plurality of pixel circuits, and the other end of the (1-4)-th connection wiring may be connected to a pixel electrode of one of the plurality of corner light-emitting elements through a contact hole.

One of the plurality of connection wirings may include a (2-3)-th connection wiring disposed on the second layer, and one end of the (2-3)-th connection wiring may be connected to one of the plurality of pixel circuits, and the other end of the (2-3)-th connection wiring may be connected to a pixel electrode of one of the plurality of corner light-emitting elements through a contact hole.

The first connection wirings and the second connection wirings may include transparent conductive materials.

A resolution of the front display area may be the same as a resolution of the plurality of corner light-emitting element.

The display panel may further include a component area inside the front display area and including a transmission area and a transition area between the component area and the front display area, and the display apparatus may further include auxiliary light-emitting elements arranged in the component area, auxiliary pixel circuits arranged in the transition area and configured to drive the auxiliary light-emitting elements, and a plurality of transparent connection wirings connecting the auxiliary pixel circuits and the auxiliary light-emitting elements to each other, and the plurality of transparent connection wirings may include a first transparent connection wiring disposed on the first layer and a second transparent connection wiring disposed on the second layer.

The display panel may further include a component area inside the front display area, and a component corresponding to the component area may be further disposed at a lower portion of the display panel.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a display apparatus according to an embodiment;

FIG. 2 is an exploded perspective view schematically illustrating a display panel and a cover window of a display apparatus according to an embodiment;

FIG. 3 is a perspective view schematically illustrating a display panel of a display apparatus according to an embodiment;

FIG. 4 is a cross-sectional view of the display apparatus of FIG. 1 taken along line I-I′ of FIG. 1;

FIG. 5 is a schematic plan view illustrating an unfolded state of a display panel that may be included in the display apparatus of FIG. 1, according to an embodiment;

FIG. 6 is an enlarged view of a portion II of FIG. 5;

FIG. 7 is a cross-sectional view schematically illustrating a portion of a cross-section of a display panel according to an embodiment, and is a cross-sectional view corresponding to line III-III′ of FIG. 6;

FIG. 8 is an equivalent circuit diagram of a pixel circuit that may be applied to a display panel according to an embodiment;

FIG. 9 is a layout view schematically illustrating a pixel arrangement structure applicable to a front display area and an arrangement of a pixel electrode which is one electrode of a light-emitting element according to an embodiment;

FIG. 10 is a layout view schematically illustrating a pixel arrangement structure applicable to a corner display area and an arrangement of a pixel electrode which is one electrode of a light-emitting element according to an embodiment;

FIG. 11 is a schematic layout view of some corner light-emitting elements, some pixel circuits, and some connection wirings arranged in a corner display area of a display panel according to an embodiment;

FIG. 12 is a cross-sectional view schematically illustrating a portion of a display panel according to an embodiment;

FIG. 13 is a cross-sectional view schematically illustrating a portion of a display panel according to an embodiment;

FIG. 14 is a cross-sectional view schematically illustrating a portion of a display panel according to an embodiment;

FIG. 15 is a cross-sectional view schematically illustrating a portion of a display panel according to an embodiment;

FIG. 16 is a schematic plan view illustrating an unfolded state of a portion of a display panel according to an embodiment; and

FIG. 17 is a schematic cross-sectional view corresponding to line IV-IV′ of FIG. 16.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.” Throughout the disclosure, the expression “at least one of a, b and c” indicates only a, only b, only c, both a and b, both a and c, both b and c, all of a, b, and c, or variations thereof.

Since various modifications and various embodiments of the present disclosure are possible, specific embodiments are illustrated in the drawings and described in detail in the detailed description. Effects and features of the present disclosure, and a method of achieving them will be apparent with reference to embodiments described below in detail in conjunction with the drawings. However, the present disclosure is not limited to the embodiments disclosed herein, but may be implemented in a variety of forms.

Hereinafter, embodiments of the present disclosure will be described in detail with reference to the accompanying drawings, and the same or corresponding components are denoted by the same reference numerals, and the same reference numerals are assigned and redundant explanations will be omitted.

In the following embodiments, when a component such as a layer, a film, a region, a plate or the like is “on” another component, this is not only when the component is “directly on” another component, but also when other components are interposed therebetween. In the drawings, for convenience of explanation, the sizes of components may be exaggerated or reduced. For example, since the size and thickness of each component shown in the drawings are arbitrarily indicated for convenience of explanation, the present disclosure is not necessarily limited to the illustration.

In the following embodiments, the x direction, the y direction, and the z direction are not limited to directions indicated by three axes on a Cartesian coordinate system, and may be interpreted in a broad sense including the same. For example, the x direction, the y direction, and the z direction may be perpendicular to each other (i.e. at right angles or 90°), but may refer to different directions that are intersect to each other but not at right angles (i.e. 90°).

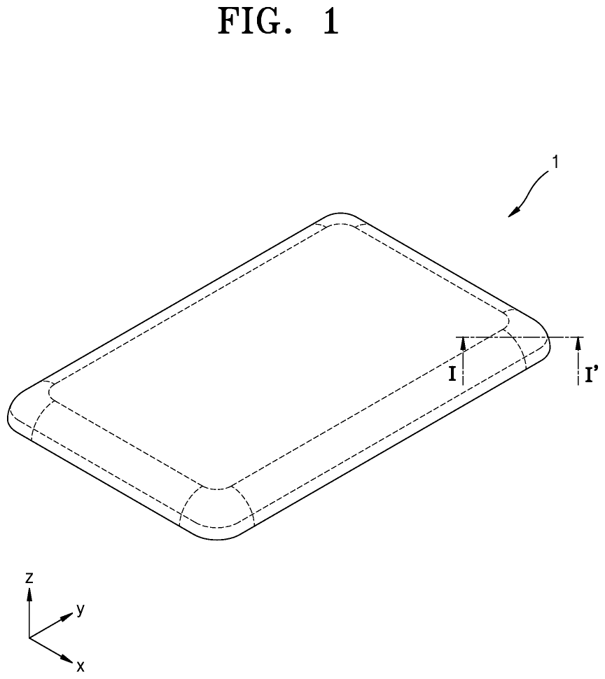

FIG. 1 is a perspective view schematically illustrating a display apparatus 1 according to an embodiment.

Referring to FIG. 1, the display apparatus 1 according to an embodiment is an apparatus for displaying a moving image or a still image and may be a portable electronic apparatus such as a mobile phone, a smartphone, a tablet personal computer (PC), and a mobile communication terminal, an electronic notebook, an electronic book, a portable multimedia player (PMP), a navigation device, an ultra mobile PC (UMPC), or the like. Also, the display apparatus 1 may be an electronic apparatus for providing a display screen such as a television, a laptop computer, a monitor, a billboard, Internet of Things (IOT) device, or the like. Alternatively, the display apparatus 1 may be a wearable device such as a smart watch, a watch phone, a glasses type display or a head mounted display (HMD).

In an embodiment, the display apparatus 1 may have a rectangular shape in a plan view. As an alternative embodiment, the display apparatus 1 may have various shapes such as a polygon such as a triangle, other polygon other than a triangle, a rectangle, and the like, a circle, and an oval. In an embodiment, when the display apparatus 1 has a polygonal shape in a plan view, polygonal corners may be rounded. Hereinafter, for convenience of explanation, the case where the display apparatus 1 has a rectangular shape with rounded corners in a plan view, will be described.

The display apparatus 1 may have short sides in a first direction (e.g., x direction or-x direction) and long sides in a second direction (e.g., y direction or-y direction). In another embodiment, in the display apparatus 1, the length of a side in the first direction (e.g., x direction or −x direction) and the length of a side in the second direction (e.g., y direction or −y direction) may be the same. In another embodiment, the display apparatus 1 may have short sides in the first direction (e.g., x direction or-x direction) and long sides in the second direction (e.g., y direction or −y direction). Each corner in which short sides in the first direction (e.g., x direction or −x direction) and long sides in the second direction (e.g., y direction or −y direction) meet each other, may be rounded to have a certain curvature.

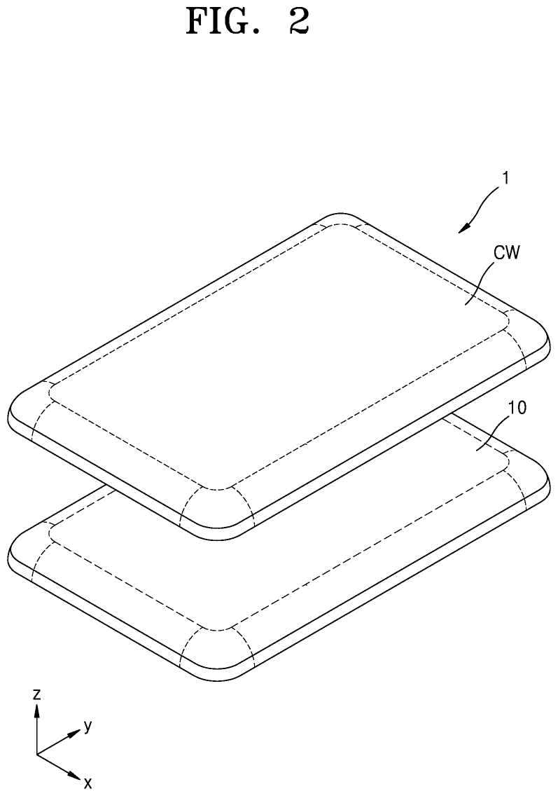

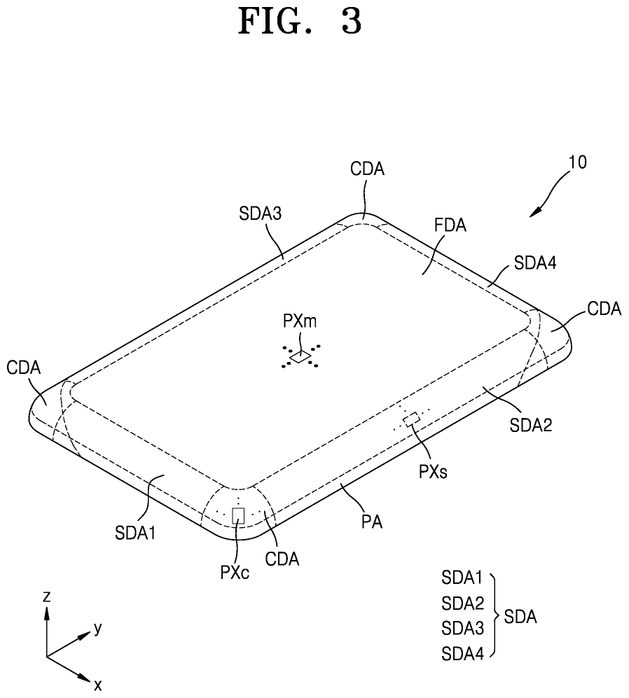

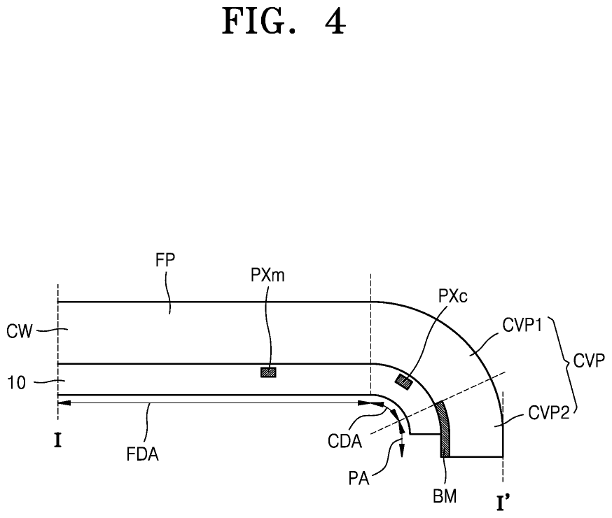

FIG. 2 is an exploded perspective view schematically illustrating a display panel 10 and a cover window CW of the display apparatus 1 according to an embodiment. FIG. 3 is a perspective view schematically illustrating the display panel 10 of the display apparatus 1 (see FIG. 1) according to an embodiment. FIG. 4 is a cross-sectional view of the display apparatus 1 (see FIG. 1) taken along a line I-I′ of FIG. 1.

Referring to FIGS. 2 through 4, the display apparatus 1 may include the display panel 10 and the cover window CW disposed on the display panel 10.

The display panel 10 may include a front display area FDA, a side display area SDA, and a corner display area CDA as a display area. The display apparatus 1 may include a peripheral area PA surrounding the display area.

The front display area FDA may be an area on a front surface of the display panel 10 and may not be bent but may be flat. The ratio of the front display area FDA in the display area of the display panel 10 may be the largest, and thus most images may be provided from the front display area FDA (e.g., in a z direction). That is, the front display area FDA may be a main display area. The front display area FDA may have a rectangular shape including short sides in the x direction, long sides in the y direction, and each round corner in which a short side and a long side meet each other.

At least a portion of the side display area SDA may be bent so that the side display area SDA includes a curved surface, and the side display area SDA may extend from each side of the front display area FDA outwards. The side display area SDA may include a first side display area SDA1, a second side display area SDA2, a third side display area SDA3, and a fourth side display area SDA4. In some embodiments, at least one of the first side display area SDA1, the second side display area SDA2, the third side display area SDA3, and the fourth side display area SDA4 may be omitted.

The first side display area SDA1 may extend from a first side of the front display area FDA and may be bent with a certain curvature. The first side display area SDA1 may extend from a lower side of the front display area FDA. The first side display area SDA1 may be an area on a lower side surface of the display panel 10.

The second side display area SDA2 may extend from a second side of the front display area FDA and may be bent with a certain curvature. The second side display area SDA2 may extend from a right side of the front display area FDA. The second side display area SDA2 may be an area on a right side surface of the display panel 10.

The third side display area SDA3 may extend from a third side of the front display area FDA and may be bent with a certain curvature. The third side display area SDA3 may extend from a left side of the front display area FDA. The third side display area SDA3 may be an area on a left side surface of the display panel 10.

The fourth side display area SDA4 may extend from a fourth of the front display area FDA and may be bent with a certain curvature. The fourth side display area SDA4 may extend from an upper side of the front side display area FDA. The fourth side display area SDA4 may be an area on an upper side surface of the display panel 10.

Each of the first through fourth side display areas SDA1, SDA2, SDA3, and SDA4 may include a curved surface bent with a certain curvature. For example, the first side display area SDA1 and the fourth side display area SDA4 may have curved surfaces bent with respect to a bending axis extending in the x direction, and the second side display area SDA2 and the third side display area SDA3 may have curved surfaces bent with respect to a bending axis extending in the y direction. Curvatures of the first through fourth side display areas SDA1, SDA2, SDA3, and SDA4 may be the same or different from each other.

The corner display area CDA may extend from a corner of the front display area FDA and may be bent with a certain curvature. The corner display area CDA may be between the first through fourth side display areas SDA1 through SDA4. For example, the corner display area CDA may be between the first side display area SDA1 and the second side display area SDA2, between the first side display area SDA1 and the third side display area SDA3, between the second side display area SDA2 and the fourth side display area SDA4, and between the third side display area SDA3 and the fourth side display area SDA4.

Since the corner display area CDA is between adjacent side display areas SDA having bent curved surfaces in different directions, the corner display area CDA may include curved surfaces in which bent curved surfaces in various directions are continuously connected to each other. In addition, when curvatures of adjacent side display areas SDA are different from each other, the curvature of the corner display area CDA may change gradually along edges of the display apparatus 1. For example, when the curvature of the first side display area SDA1 is different from the curvature of the second side display area SDA2, the corner display area CDA between the first side display area SDA1 and the second side display area SDA2 may have a curvature that gradually changes according to a position.

The display panel 10 may provide an image using main pixels PXm disposed in the front display area FDA, side pixels PXs disposed in the side display area SDA, and corner pixels PXc disposed in the corner display area CDA. Since images may be provided to the side display area SDA and the corner display area CDA in addition to the front display area FDA, the ratio of the display area of the display panel 10 in the display apparatus 1 may be increased. That is, in the display apparatus 1 having the same size, the area of the peripheral area PA may be reduced, and the area of the display area may be increased.

The peripheral area PA may be disposed to entirely or partially surround the outside of the side display area SDA and the corner display area CDA. The peripheral area PA may be an area in which no images are displayed, and various wirings and driving circuits may be disposed in the peripheral area PA. A shielding film such as a light blocking member may be provided in the peripheral area PA so that members disposed in the peripheral area PA are not visible.

Referring to FIG. 4, the cover window CW may be disposed on a front surface of the display panel 10. Here, the ‘front surface’ of the display panel 10 may be defined as a surface facing a direction in which the display panel 10 provides an image.

The cover window CW may be configured to cover and protect the display panel 10. The cover window CW may have a high transmittance to transmit light emitted from the display panel 10, and may have a small thickness to minimize the weight of the display apparatus 1. In addition, the cover window CW may have a strong strength and hardness to protect the display panel 10 from an external impact.

The cover window CW may include a transparent material. The cover window CW may include, for example, glass or plastic. When the cover window CW includes plastic, the cover window CW may be flexible. For example, the cover window CW may be Ultra-Thin Glass, (UTG®) having enhanced strength by using a method such as chemical strengthening or thermal strengthening. In another embodiment, the cover window CW may be reinforced glass and colorless polyimide (CPI). In an embodiment, the cover window CW may have a structure in which a flexible polymer layer is disposed on one surface of a glass substrate, or may include only a polymer layer.

The cover window CW may include a flat surface portion FP corresponding to the front display area FDA of the display panel 10, and a curved surface portion CVP corresponding to the side display area SDA and the corner display area CDA.

The flat surface portion FP of the cover window CW may be provided as a flat surface and may overlap the front display area FDA of the display panel 10. The curved surface portion CVP of the cover window CW may include a curved surface, and in this case, the curved surface portion CVP of the cover window CW may have a certain curvature or a varying curvature. The curved surface portion CVP may include a first curved surface portion CVP1 and a second curved surface portion CVP2. The first curved surface portion CVP1 may overlap the side display area SDA and the corner display area CDA of the display panel 10. The second curved surface portion CVP2 may overlap the peripheral area PA of the display panel 10. The first curved surface portion CVP1 may be disposed between the flat surface portion FP and the second curved surface portion CVP2.

A light blocking member BM may be disposed on a portion of the second curved surface portion CVP2 of the cover window CW. The light blocking member BM for covering a lower structure thereunder may overlap the peripheral area PA of the display panel 10. The light blocking member BM may include a light blocking material. The light blocking member BM may include carbon black, carbon nanotubes, and a resin including a black dye. Alternatively, the light blocking member BM may include nickel, aluminum, molybdenum, and an alloy thereof. The light blocking member BM may be coated with an inkjet or attached as a film type.

The display panel 10 may be disposed under the cover window CW. The cover window CW and the display panel 10 may be combined with each other via an adhesive member (not shown). The adhesive member may be an optically cleared adhesive (OCA) film or an optically cleared resin (OCR) film.

The display panel 10 may provide an image using main pixels PXm disposed in the front display area FDA and corner pixels PXc disposed in the corner display area CDA. A lower protection film (not shown) for protecting the display panel 10 may be further disposed under the display panel 10.

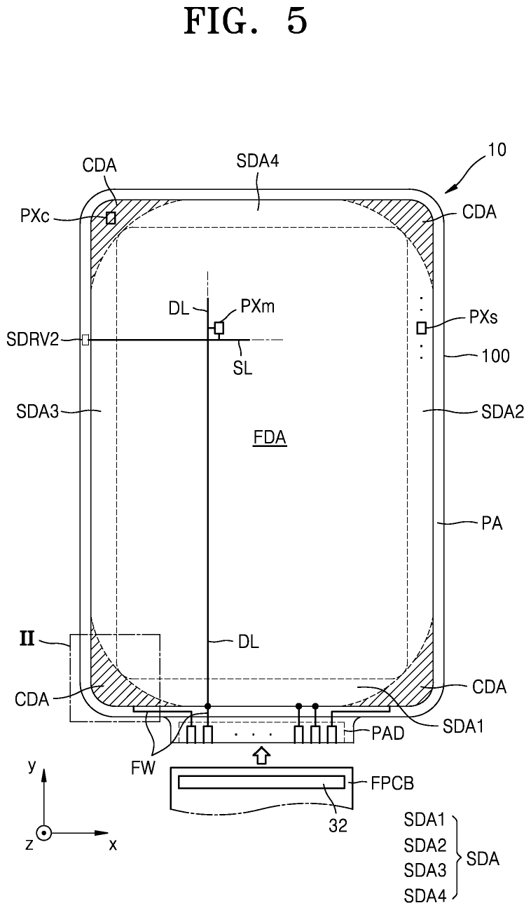

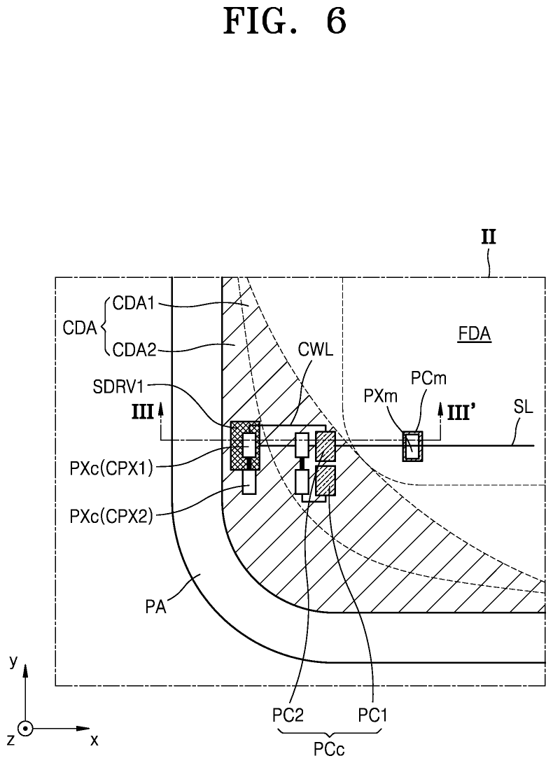

FIG. 5 is a schematic plan view illustrating an unfolded state of a display panel 10 that may be included in the display apparatus 1 of FIG. 1, according to an embodiment. FIG. 6 is an enlarged view of a portion II of FIG. 5.

Referring to FIGS. 5 and 6, various components that constitute the display panel 10 may be disposed on the substrate 100. The substrate 100 may include a front display area FDA, a side display area SDA, a corner display area CDA, and a peripheral area PA.

A plurality of main pixels PXm may be arranged in the front display area FDA, and main images may be displayed by the plurality of main pixels PXm. The main pixels PXm may be provided as a set of a plurality of sub-pixels. Each of the plurality of sub-pixels may emit red, green, blue or white light.

The side display area SDA may be disposed on upper, lower, left, and right sides of the front display area FDA. A plurality of side pixels PXs may be arranged in the side display area SDA, and side images may be displayed by the plurality of side pixels PXs. The side image may form one full image with the main image, or the side image may be an independent image from the main image.

The corner display area CDA may be disposed in an area extending from the corner of the front display area FDA. The corner display area CDA may be between two side display areas SDA. A plurality of corner pixels PXc may be arranged in the corner display area CDA, and corner images may be displayed by the plurality of corner pixels PXc. The corner image may form one full image with the main image and the side image, or the corner image may be an independent image from the main image.

The corner display area CDA may include a first corner display area CDA1 and a second corner display area CDA2. The second corner display area CDA2 that is an area extending from the first corner display area CDA1 may be disposed at an edge of the substrate 100 than the first corner display area CDA1. The first corner display area CDA1 may be disposed between the second corner display area CDA2 and the front display area FDA.

A driving circuit SDRV1 may be disposed in the second corner display area CDA2 in addition to the corner pixel PXc. The driving circuit SDRV1 may provide scan signals for driving the main pixels PXm and the corner pixels PXc arranged in the front display area FDA and the corner display area CDA. In some embodiments, the driving circuit SDRV1 may be simultaneously connected to a pixel circuit for driving the corner pixel PXc and a pixel circuit for driving the main pixels PXm and may provide the same scan signal. In this case, the scan line SL connected to the driving circuit SDRV1 may extend from the second corner display area CDA2 to the front display area FDA. The scan line SL may extend in the x direction.

In the second corner display area CDA2, the corner pixels PXc may overlap the driving circuit SDRV1. The pixel circuit PC2 for driving the corner pixels PXc arranged in the second corner display area CDA2 may be disposed in the first corner display area CDA1. Thus, pixel circuits PC1 and PC2 respectively for driving the corner pixels PXc disposed in the first corner display area CDA1 and the corner pixels PXc disposed in the second corner display area CDA2 may be arranged in the first corner display area CDA1. The corner pixel PXc arranged in the second corner display area CDA2 may be connected to the pixel circuit and PC2 arranged in the first corner display area CDA1 via a connection wiring CWL and driven. The connection wiring CWL may extend in the x direction that is a direction in which the scan line SL extends.

The corner pixels PXc arranged in the corner display area CDA may include a first copy pixel CPX1 and a second copy pixel CPX2. The first copy pixel CPX1 and the second copy pixel CPX2 may be driven by one pixel circuit and may be pixels that emit light of the same color. The sizes of the first copy pixel CPX1 and the second copy pixel CPX2 may be substantially the same. As the corner pixels PXc are provided as copy pixels, the number of a pixel circuit for driving the corner pixels PXc may be reduced, and since the corner pixels PXc overlap the driving circuit SDRV1, the expansion of the corner display area CDA is possible.

The peripheral area PA may be arranged outside the side display area SDA and the corner display area CDA. Various wirings, a driving circuit SDRV2, and a terminal portion PAD may be provided in the peripheral area PA.

The driving circuit SDRV2 may provide scan signals for driving the main pixels PXm and the side pixels PXs. The driving circuit SDRV2 may be arranged on the right side of the second side display area SDA2 or the left side of the third side display area SDA3 and may be connected to the scan line SL extending in the x direction.

The terminal portion PAD may be disposed at a lower side of the first side display area SDA1. The terminal portion PAD may not be covered by an insulating layer but may be exposed and connected to a display circuit board FPCB. A display driving unit 32 may be disposed on the display circuit board FPCB.

The display driving unit 32 may generate control signals to be transmitted to the driving circuits SDRV1 and SDRV2. Also, the display driving unit 32 may generate data signals. The generated data signals may be transmitted to the pixels PXm, PXs, and PXc via a fanout wiring FW and a data line DL connected to the fanout wiring FW.

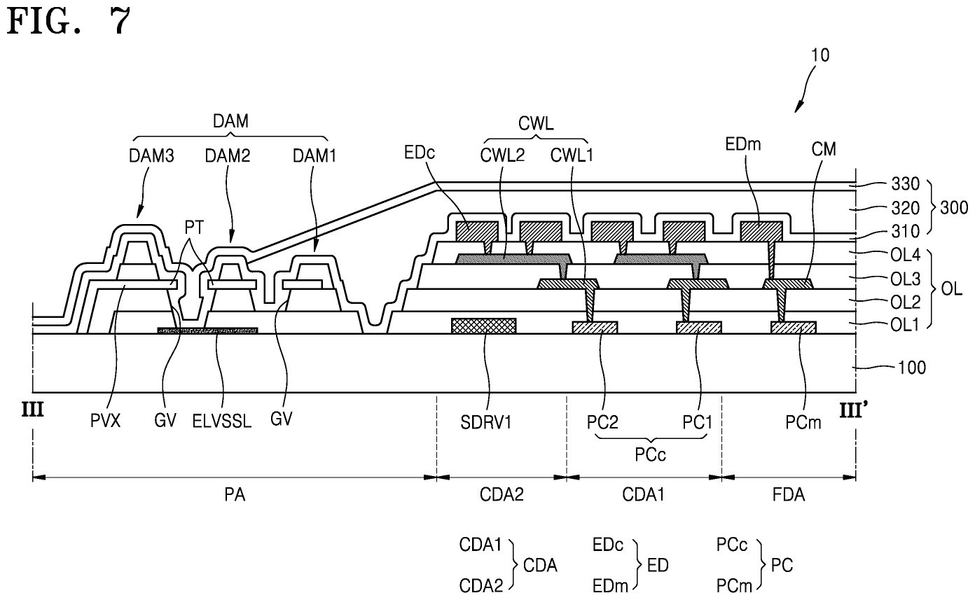

FIG. 7 is a cross-sectional view schematically illustrating a portion of a cross-section of the display panel 10 (see FIG. 5) according to an embodiment, and is a cross-sectional view corresponding to a line III-III′ of FIG. 6.

Referring to FIG. 7, the display panel 10 may include a front display area FDA, a corner display area CDA, and a peripheral area PA, and the corner display area CDA may include a first corner display area CDA1 and a second corner display area CDA2.

The substrate 100 may include an insulating material such as glass, quartz, polymer resin or the like. The substrate 100 may be a rigid substrate or a flexible substrate that may be bent, folded or rolled.

Pixel circuits PCm and PCc including thin film transistors, a driving circuit SDRV1 for providing scan signals to the pixel circuits PCm and PCc, light-emitting elements EDm and EDc connected to the pixel circuits PCm and PCc and for implementing emission of pixels, a thin film encapsulation layer 300 for covering and protecting the light-emitting elements EDm and EDc, and a dam DAM may be arranged on the substrate 100. The pixel circuits PCm and PCc may include a main pixel circuit PCm and a corner pixel circuit PCc, and the corner pixel circuit PCc may include a first corner pixel circuit PC1 and a second corner pixel circuit PC2. In some embodiments, all of the main pixel circuit PCm, the first corner pixel circuit PC1, and the second corner pixel circuit PC2 may be provided as the same pixel circuit. In another embodiment, at least a portion of the main pixel circuit PCm, the first corner pixel circuit PC1, and the second corner pixel circuit PC2 may be modified or provided as different pixel circuits.

An organic insulating layer OL may be disposed between the pixel circuits PCm and PCc and the light-emitting elements EDm and EDc. The organic insulating layer OL may be provided by stacking a plurality of organic insulating layers. In some embodiments, the organic insulating layer OL may be provided by stacking a first organic insulating layer OL1, a second organic insulating layer OL2, a third organic insulating layer OL3, and a fourth organic insulating layer OL4.

The main pixel circuit PCm and the main light-emitting element EDm connected to the main pixel circuit PCm may be arranged in the front display area FDA of the display panel 10. A light-emitting area of the main light-emitting element EDm may correspond to the main pixel (see the main pixel PXm of FIG. 6). The main pixel circuit PCm may include at least one thin film transistor and may control emission of the main light-emitting element EDm. The main light-emitting element EDm may be connected to the main pixel circuit PCm via the connection electrode CM. At least a portion of the main light-emitting element EDm may overlap the main pixel circuit PCm.

The corner pixel circuit PCc and the corner light-emitting element EDc connected to the corner pixel circuit PCc may be arranged in the front display area CDA of the display panel 10. A light-emitting area of the corner light-emitting element EDc may correspond to the corner pixel (see the corner pixel PXc of FIG. 6). The first corner pixel circuit PC1 may include at least one thin film transistors and may control emission of at least two corner light-emitting element EDc. In an embodiment, two corner light-emitting elements EDc may be connected to one first corner pixel circuit PC1 and may emit light simultaneously. In this case, two corner light-emitting elements EDc may implement copy pixels.

The second corner pixel circuit PC2 connected to the corner light-emitting element EDc disposed in the second corner display area CDA2 may be arranged in the first corner display area CDA1. The second corner pixel circuit PC2 may include at least one thin film transistors and may control emission of at least two corner light-emitting element EDc. In an embodiment, two corner light-emitting elements EDc may be connected to one first corner pixel circuit PC1 and may emit light simultaneously. In this case, two corner light-emitting elements EDc may implement copy pixels.

The second corner pixel circuit PC2 may be connected to the corner light-emitting element EDc disposed in the second corner display area CDA2 by the connection wiring CWL connected to the first corner display area CDA1. The connection wiring CWL may include a first connection wiring CWL1 and a second connection wiring CWL2, which are arranged in different layers. The connection relationship in which the second corner pixel circuit PC2 may be connected to the corner light-emitting element EDc via only the first connection wiring CWL1, the corner light-emitting element EDc via only the second connection wiring CWL2 or the corner light-emitting element EDc via the first connection wiring CWL1 and the second connection wiring CWL2, may be variously modified.

The driving circuit SDRV1 may be disposed in the second corner display area CDA2 of the display panel 10 (see FIG. 5). The driving circuit SDRV1 may include at least one thin film transistor and may provide scan signals to the pixel circuits PCc and PCm arranged in the corner display area CDA and the front display area FDA. A light-emitting control driving circuit (not shown) for providing light-emitting control signals in addition to scan signals may be further disposed in the second corner display area CDA2. The driving circuit SDRV1 and the light-emitting control driving circuit may overlap the corner light-emitting element EDc.

A light-emitting area of the corner light-emitting element EDc arranged in the first corner display area CDA1 and the second corner display area CDA2 may represent corner pixels PXc, and the corner pixels PXc may be arranged in the same pixel arrangement in the first corner display area CDA1 and the second corner display area CDA2.

The main light-emitting element EDm and the corner light-emitting element EDc may be covered by the thin film encapsulation layer 300. In some embodiments, the thin film encapsulation layer 300 may include at least one inorganic encapsulation layer and at least one organic encapsulation layer. In an embodiment, the thin film encapsulation layer 300 may include first and second inorganic encapsulation layers 310 and 330 and an organic encapsulation layer 320 between the first and second inorganic encapsulation layers 310 and 330.

A common voltage line ELVSSL for transmitting a common voltage to the light-emitting element and a plurality of dams DAM may be arranged in the peripheral area PA of the display panel 10. The plurality of dams DAM may overlap the common voltage line ELVSSL. The plurality of dams may prevent a flow of the organic encapsulation layer 320 of the thin film encapsulation layer 300 and prevent external moisture permeation.

The plurality of dams DAM may include a first dam DAM1, a second dam DAM2, and a third dam DAM3. A groove GV that is concave in a depth direction may be formed between the plurality of dams DAM. The plurality of dams DAM may be provided by stacking a plurality of organic insulating layers OL. Each of the first dam DAM1 and the second dam DAM2 may be provided by stacking a first organic insulating layer OL1, a second organic insulating layer OL2, and a third organic insulating layer OL3.

In the present embodiment, each of the first dam DAM1 and the second dam DAM2 may further include an inorganic protection layer PVX disposed between the second organic insulating layer OL2 and the third organic insulating layer OL3. The inorganic protection layer PVX may have a protrusion tip PT that protrudes in a center direction of the groove GV between the first dam DAM1 and the second dam DAM2. As an organic layer or an opposite electrode included in the light-emitting element is disconnected by the protrusion tip, a tolerance margin required to deposit the organic layer or the opposite electrode may be reduced so that the area of the peripheral area PA may be remarkably reduced.

In the present embodiment, the third dam DAM3 may be provided by stacking the first organic insulating layer OL1, the second organic insulating layer OL2, the third organic insulating layer OL3, and the fourth organic insulating layer OL4. The third dam DAM3 may further include an inorganic protection layer PVX between the second organic insulating layer OL2 and the third organic insulating layer OL3. The inorganic protection layer PVX may cover a side surface of the third dam DAM3 adjacent to the edge of the substrate 100. That is, the inorganic protection layer PVX may be provided to cover one side surface of the second organic insulating layer OL2 that is a second layer of the third dam DAM3. The inorganic protection layer PVX may extend from one side surface of the second organic insulating layer OL2 and may be disposed up to a top surface of the substrate 100. Thus, the first inorganic encapsulation layer 310 of the thin film encapsulation layer 300 may be in contact with the inorganic protection layer PVX on the side surface of the third dam DAM3. The second inorganic encapsulation layer 330 may also be in contact with the first inorganic encapsulation layer 310 on the side surface of the third dam DAM3.

The first inorganic encapsulation layer 310 may clad the edge of the inorganic protection layer PVX on a top surface of the substrate 100, and the second inorganic encapsulation layer 330 may clad the edge of the first inorganic encapsulation layer 310 on the top surface of the substrate 100. By using such a structure, external air may be effectively prevented from permeating into the display area. Also, because the first inorganic encapsulation layer 310, the second inorganic encapsulation layer 330, and the inorganic protection layer PVX may be in contact with the side surface of the third dam DAM3, the area of the peripheral area PA may be remarkably reduced. The area of the second corner display area CDA2 may be increased by reducing the area of the peripheral area PA, and this may mean that the area of the display area of the display apparatus 1 (see FIG. 1) increases.

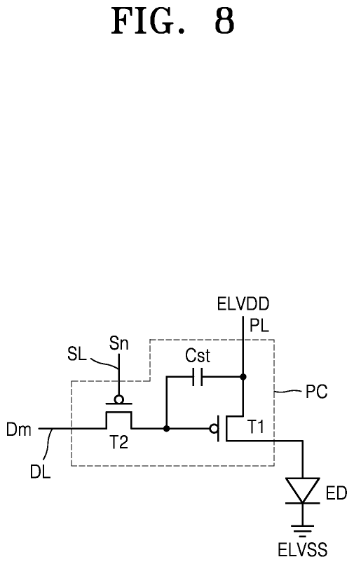

FIG. 8 is an equivalent circuit diagram of a pixel circuit PC that may be applied to a display panel 10 (see FIG. 5) according to an embodiment.

Referring to FIG. 8, the pixel circuit PC may be connected to the light-emitting element ED and may implement emission of (sub-)pixels. The pixel circuit PC may include a driving thin film transistor T1, a switching thin film transistor T2, and a storage capacitor Cst. The switching thin film transistor T2 may be connected to the scan line SL and the data line DL and may be configured to transmit a data signal Dm input through the data line DL in response to a scan signal Sn input through the scan line SL to the driving thin film transistor T1.

The storage capacitor Cst may be connected to the switching thin film transistor T2 and the driving voltage line PL and may be configured to store a voltage corresponding to a difference between the voltage transmitted from the switching thin film transistor T2 and the driving voltage ELVDD supplied to the driving voltage line PL.

The driving thin film transistor T1 may be connected to the driving voltage line PL and the storage capacitor Cst and may be configured to control a driving current flowing through the light-emitting element ED from the driving voltage line PL in response to a voltage stored in the storage capacitor Cst. The light-emitting element ED may emit light having certain brightness by the driving current.

FIG. 8 illustrates the case where the pixel circuit PC includes two thin film transistors and one storage capacitor, but embodiments are not limited thereto. Various modifications that the pixel circuit PC may include 3 to 9 thin film transistors and 1 to 2 capacitors, are possible. The pixel circuit PC may be equally applied to a main pixel circuit PCm (see FIG. 7) and the corner pixel circuit PCc (see FIG. 7), and may be variously modified such as deformation of some components. For example, the capacity of the storage capacitor included in the main pixel circuit PCm and the capacity of the storage capacitor included in the corner pixel circuit PCc may be different from each other. Alternatively, the number of thin film transistors included in the main pixel circuit PCm and the number of thin film transistors included in the corner pixel circuit PCc may be different from each other, and may be variously modified.

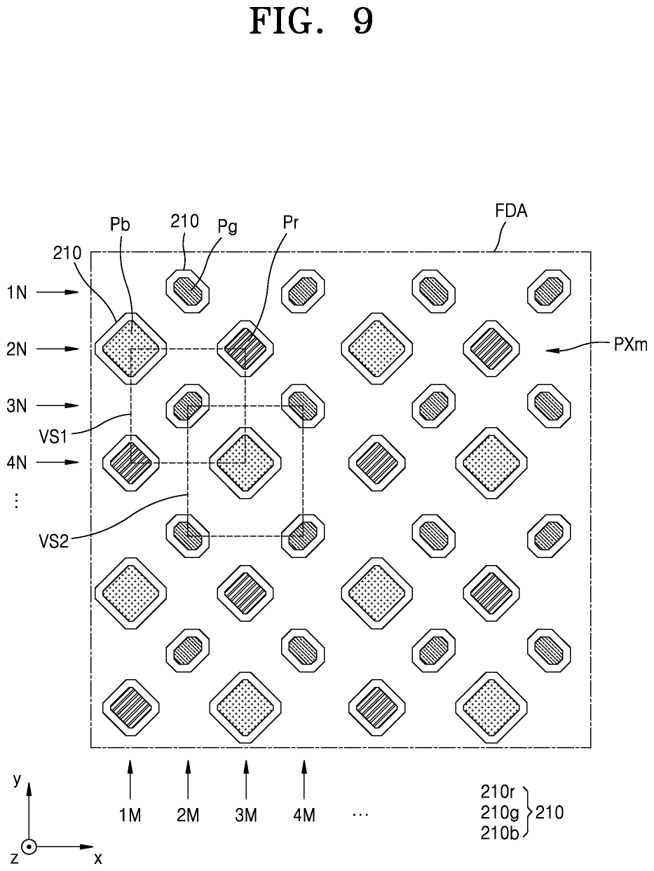

FIG. 9 is a layout view schematically illustrating a pixel arrangement structure applicable to the front display area FDA and an arrangement of a pixel electrode which is one electrode of a light-emitting element ED (see FIG. 7) according to an embodiment.

Referring to FIG. 9, a plurality of sub-pixels Pr, Pg, and Pb may be arranged in the front display area FDA. In the present specification, sub-pixels may be a minimum unit for implementing an images and mean a light-emitting area of a light-emitting element ED. The plurality of sub-pixels Pr, Pg, and Pb may include a first sub-pixel Pr, a second sub-pixel Pg, and a third sub-pixel Pb. The first sub-pixel Pr, the second sub-pixel Pg, and the third sub-pixel Pb may realize red, green, and blue colors, respectively.

As shown in FIG. 9, the first sub-pixel Pr, the second sub-pixel Pg, and the third sub-pixel Pb may be arranged in a diamond PenTile® arrangement structure in the front display area FDA. In FIG. 9, 1N, 2N, 3N, 4N, and . . . represent rows of sub-pixels, and 1M, 2M, 3M, 4M, and . . . represent columns of the sub-pixels.

A plurality of second sub-pixels Pg may be disposed to be spaced apart from each other by a certain distance in a first row 1N, a plurality of third sub-pixels Pb and a plurality of first sub-pixels Pr may be alternately disposed in an second row 2N adjacent to the first row 1N, a plurality of second sub-pixels Pg may be disposed to be spaced apart from each other by a certain distance in a third row 3N adjacent to the second row 2N, and the first sub-pixel Pr and the third sub-pixel Pb may be alternately disposed in a fourth row 4N adjacent to the third row 3N, and the arrangement of the sub-pixels may be repeated up to a N-th row. In this case, the third sub-pixel Pb and the first sub-pixel Pr may be provided to be greater than the second sub-pixel Pg in an area.

The plurality of second sub-pixels Pg arranged in the first row 1N and the plurality of first sub-pixels Pr and the plurality of third sub-pixel Pb arranged in the second row 2N may be alternately arranged. The third sub-pixel Pb and the first sub-pixel Pr may be alternately disposed in the first column 1M, and a plurality of second sub-pixels Pg may be disposed to be spaced apart from each other at a certain distance in a second column 2M adjacent to the first column 1M, and the first sub-pixel Pr and the third sub-pixel Pb may be alternately disposed in a third column 3M adjacent to the second column 2M, and a plurality of second sub-pixels Pg may be disposed to be spaced apart from each other at a certain distance in a fourth column 4M adjacent to the third column 3M, and the arrangement of the sub-pixels may be repeated up to a M-th column.

When the pixel array structure is expressed differently, the first sub-pixel Pr may be disposed at first and third vertices facing each other of a first virtual rectangle VS1 having the center point of the second sub-pixel Pg as the center point of the rectangle. The third sub-pixel Pb may be disposed at the second and fourth vertices facing each other of the first virtual rectangle VS1.

When the above-described pixel arrangement structure is expressed differently, it may be expressed that the second sub-pixel Pg is disposed at a vertex of a second virtual rectangle VS2 having a center point of the first sub-pixel Pr or the third sub-pixel Pb as a center point of a rectangle. In this case, the first and second virtual rectangles VS1 and VS2 may be variously modified like a diamond, a square, and the like.

The above-described pixel array structure is referred to as a diamond PenTile® arrangement structure, and it is possible to implement high resolution with a small number of sub-pixels by applying rendering driving representing colors by sharing adjacent sub-pixels.

The first sub-pixel Pr, the second sub-pixel Pg, and the third sub-pixel Pb arranged in the front display area FDA may represent a light-emitting area of each of main light-emitting elements EDm (see FIG. 7), and each of the main light-emitting elements EDm may include spaced pixel electrodes 210.

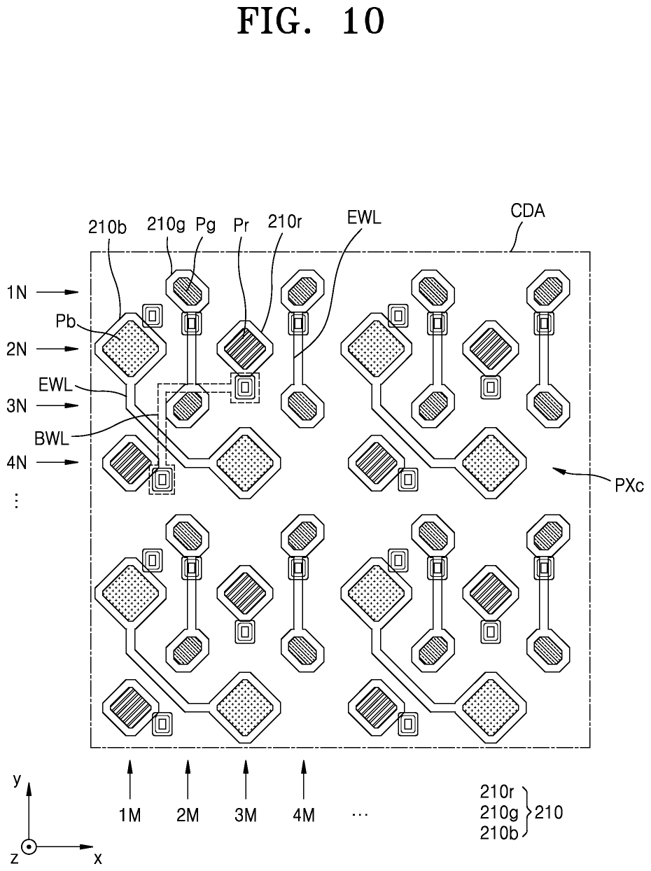

FIG. 10 is a layout view schematically illustrating a pixel arrangement structure applicable to the corner display area CDA and an arrangement of a pixel electrode which is one electrode of a light-emitting element ED (see FIG. 7) according to an embodiment.

As shown in FIG. 10, the first sub-pixel Pr, the second sub-pixel Pg, and the third sub-pixel Pb may be arranged in a diamond PenTile® arrangement structure in the corner display area CDA. That is, sub-pixels Pr, Pg, and Pb arranged in each of the front display area FDA (see FIG. 9) and the corner display area CDA may have the same pixel arrangement in a plan view.

In some embodiments, the front display area FDA and the corner display area CDA may have the same resolution. In other words, the number or area of sub-pixels arranged in the front display area FDA and the number or area of sub-pixels arranged in the corner display area CDA may be the same for each area.

The first sub-pixel Pr, the second sub-pixel Pg, and the third sub-pixel Pb arranged in the corner display area CDA represent light-emitting areas of each of the corner light-emitting elements EDc (see FIG. 7). The corner light-emitting elements may include first light-emitting elements for implementing first sub-pixels Pr, second light-emitting elements for implementing second sub-pixels Pg, and third light-emitting elements for implementing third sub-pixels Pb.

The corner light-emitting elements EDc may include at least two light-emitting elements connected to each other. The connected light-emitting elements may be connected to one pixel circuit and may emit light simultaneously. The connected light-emitting elements may implement copy pixels that represent the same color and brightness.

Referring to FIG. 10, pixel electrodes 210r of two adjacent first light-emitting elements among the first light-emitting elements may be connected to each other via a bridge wiring BWL disposed in a different layer from the pixel electrode 210r. For example, the bridge wiring BWL may be disposed on the same layer as the first connection wiring (see the first connection wiring CWL1 of FIG. 7) or on the same layer as the second connection wiring (see the second connection wiring CWL2 of FIG. 7).

The pixel electrode 210g of two adjacent second light-emitting elements among the second light-emitting elements may be integrally provided. That is, two second light-emitting elements may share one pixel electrode 210g. Alternatively, pixel electrodes 210g of two second light-emitting elements may be connected to each other by an electrode wiring EWL. The electrode wiring EWL may be disposed on the same layer as the pixel electrode 210g, and the pixel electrode 210g and the electrode wiring EWL may be integrally provided.

The pixel electrode 210b of two adjacent third light-emitting elements among the third light-emitting elements may be integrally provided. That is, two third light-emitting elements may share one pixel electrode 210b. Alternatively, pixel electrodes 210b of two third light-emitting elements may be connected to each other by the electrode wiring EWL.

Since the wiring connecting the corner light-emitting elements EDc in the corner display area CDA is used as the electrode wiring EWL disposed on the same layer as the pixel electrode 210, the degree of freedom of the connection wirings CWL (see FIG. 7) disposed thereunder may be increased.

FIGS. 9 and 10 illustrate that a plurality of sub-pixels Pr, Pg, and Pb are arranged in the diamond PenTile® arrangement structure, but embodiments are not limited thereto. For example, the plurality of sub-pixels Pr, Pg, and Pb may be arranged in various arrangement structure like a stripe arrangement structure, a mosaic arrangement structure, a delta arrangement structure, and the like.

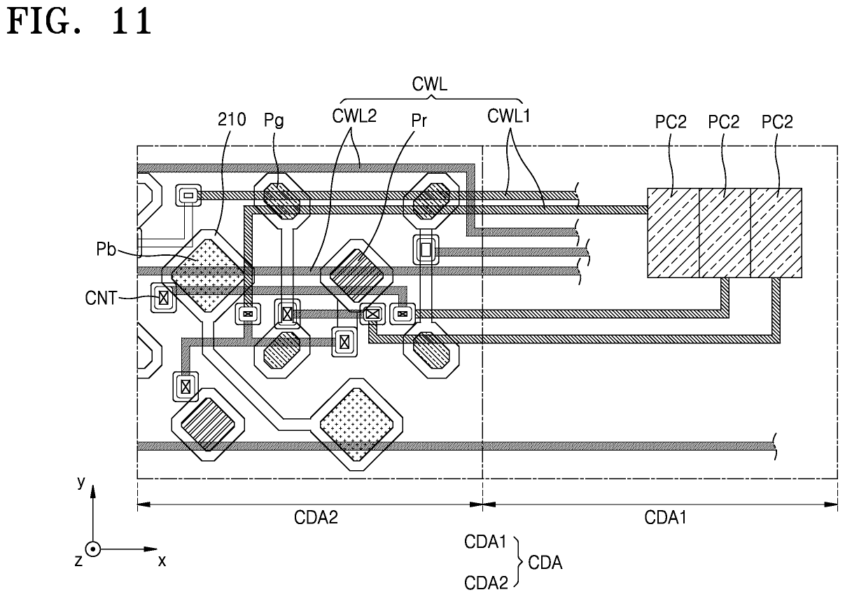

FIG. 11 is a schematic layout view of some corner light-emitting elements EDc (see FIG. 7), some pixel circuits PC (see FIG. 7), and some connection wirings CWL arranged in a corner display area CDA of a display panel 10 (see FIG. 5) according to an embodiment.

Referring to FIG. 11, in the corner display area CDA, second corner pixel circuits PC2 may be arranged in a first corner display area CDA1. Light-emitting elements arranged in the second corner display area CDA2 may be connected to the second corner pixel circuits PC2 arranged in the first corner display area CDA1 through the connection wirings CWL.

Each second corner pixel circuit PC2 arranged in the first corner display area CDA1 may be connected to a plurality of light emitting elements that emit light of the same color. For example, one second corner pixel circuit PC2 may be connected to two light-emitting elements that emit light of the same color.

The second corner pixel circuit PC2 may be electrically connected to the light-emitting element via the connection wirings CWL. The connection wiring CWL may be connected to the pixel electrode 210 of the light-emitting element via a contact hole CNT. Thus, the connection wirings CWL may extend from the first corner display area CDA1 to the second corner display area CDA2. The connection wirings CWL may generally extend in the x direction or the −x direction.

The connection wiring CWL may include first connection wirings CWL1 and second connection wirings CWL2, which are arranged in different layers. In some embodiments, some pixel circuits PC may be connected to the light-emitting element via one of the first connection wirings CWL1. In some embodiments, some pixel circuits PC may be connected to the light-emitting element via one of the second connection wirings CWL2. In some embodiment, the pixel circuits PC may be connected to one of the first connection wirings CWL1 and one of the second connection wirings CWL2. In some embodiments, some of the first connection wirings CWL1 and the second connection wirings CWL2 may be used as a bridge wiring BWL (see FIG. 10) for connecting two light-emitting elements that emit light of the same color.

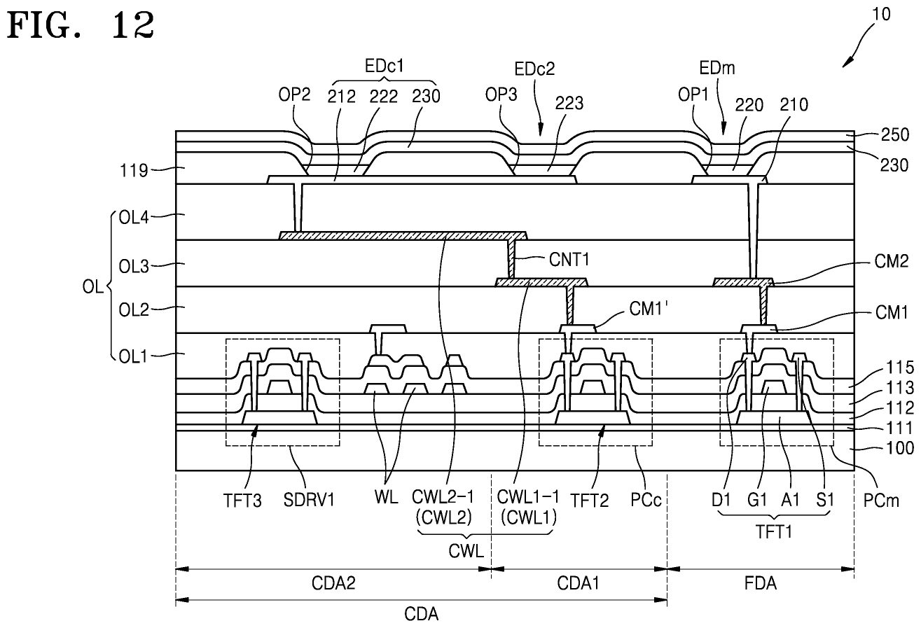

Hereinafter, a structure in which components included in the display panel 10 are stacked, will be described with reference to FIG. 12.

FIG. 12 is a cross-sectional view schematically illustrating a portion of a display panel 10 according to an embodiment. In detail, FIG. 12 represents portions of a front display area FDA and a corner display area CDA of the display panel 10 of FIG. 12.

Referring to FIG. 12, a main light-emitting element EDm and a main pixel circuit PCm connected to the main light-emitting element EDm may be arranged in the front display area FDA. Corner light-emitting elements EDc1 and EDc2 as corner light-emitting elements EDc (see FIG. 7) may be arranged in the corner display area CDA. The corner light-emitting elements EDc1 and EDc2 may include a first corner light-emitting element EDc1 and a second corner light-emitting element EDc2 that are connected to each other. The main light-emitting element EDm and the corner light-emitting elements EDc1 and EDc2 may be provided as organic light-emitting diodes.

The corner pixel circuit PCc connected to the corner light-emitting elements EDc1 and EDc2 may be arranged in the first corner display area CDA1 of the corner display area CDA. A driving circuit SDRV1 for providing a driving signal such as a scan signal to the pixel circuits PCm and PCc may be arranged in the second corner display area CDA2. The main pixel circuit PCm may include a first thin film transistor TFT1, and the corner pixel circuit PCc may include a second thin film transistor TFT2, and the driving circuit SDRV1 may include a third thin film transistor TFT3.

A connection wiring CWL for connecting the corner pixel circuit PCc to the corner light-emitting elements EDc1 and EDc2 may be arranged in the first corner display area CDA1 and the second corner display area CDA2. The connection wiring CWL may include a first connection wiring CWL1 and a second connection wiring CWL2, which are arranged in different layers.

The substrate 100 may include an insulating material such as glass, quartz, polymer resin or the like. The substrate 100 may be a rigid substrate or a flexible substrate that may be bent, folded or rolled.

The buffer layer 111 may be located on the substrate 100, may reduce or prevent penetration of foreign substances, moisture or external air from the lower portion of the substrate 100 and may provide a flat surface to the substrate 100. The buffer layer 111 may include an inorganic material such as an oxide or a nitride, an organic material, or an organic/inorganic composite material and may have a single or multi-layered structure of the inorganic material and the organic material. A barrier layer (not shown) for preventing penetration of external air may be further included between the substrate 100 and the buffer layer 111. In some embodiments, the buffer layer 111 may include silicon oxide (SiO₂) or silicon nitride (SiNₓ).

A first thin film transistor TFT1, a second thin film transistor TFT2, and a third thin film transistor TFT3 may be arranged on the buffer layer 111. The first thin film transistor TFT1 may include a first semiconductor layer A1, a first gate electrode G1, a first source electrode S1, and a first drain electrode D1. The first thin film transistor TFT1 may be connected to the main light-emitting element EDm and may drive the main light-emitting element EDm. The second thin film transistor TFT2 may be connected to the corner light-emitting elements EDc1 and EDc2 and may drive the corner light-emitting elements EDc1 and EDc2. The third thin film transistor TFT3 may provide a driving signal such as a scan signal to other thin film transistor included in the driving circuit SDRV1.

Since the second thin film transistor TFT2 and the third thin film transistor TFT3 may have a similar configuration to that of the first thin film transistor TFT1, a description of the first thin film transistor TFT1 will be described as a description of the second thin film transistor TFT2 and the third thin film transistor TFT3.

The first semiconductor layer A1 may be arranged on the buffer layer 111 and may include polysilicon. In another embodiment, the first semiconductor layer A1 may include amorphous silicon. In another embodiment, the first semiconductor layer A1 may include an oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), and zinc (Zn). The first semiconductor layer A1 may include a channel region, a source region and a drain region doped with impurities.

A first gate insulating layer 112 may be provided to at least partially cover the first semiconductor layer A1. The first gate insulating layer 112 may include an inorganic insulating material such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), or hafnium oxide (HfO₂). The first gate insulating layer 112 may be a single layer or multi-layer including the above-described inorganic insulating material.

The first gate electrode G1 may be arranged on the first gate insulating layer 112 to overlap the first semiconductor layer A1. The first gate electrode G1 may include molybdenum (Mo), aluminum (Al), copper (Cu), and titanium (Ti), and may have a single layer or multi-layered structure. In an example, the first gate electrode G1 may be a single layer of Mo.

The second gate insulating layer 113 may be provided to cover the first gate electrode G1. The second gate insulating layer 113 may include an inorganic insulating material such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnOₓ, may be ZnO or ZnO₂). The second gate insulating layer 113 may be a single layer or multi-layer including the above-described inorganic insulating material.

Wirings WL and capacitor electrodes (not shown) may be arranged on the second gate insulating layer 113. Some of the wirings WL arranged in the second corner display area CDA2 may be connected to the driving circuit SDRV1 to transmit driving signals. The wirings WL may include Al, platinum (Pt), palladium (Pd), silver (Ag), magnesium (Mg), gold (Au), nickel (Ni), neodymium (Nd), iridium (Ir), Cr, calcium (Ca), Mo, Ti, tungsten (W) or Cu, and may have a single layer or multi-layered structure of the above described material.

An interlayer insulating layer 115 may be formed on the second gate insulating layer 113 to cover the wirings WL. The interlayer insulating layer 115 may include an inorganic insulating material such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), or hafnium oxide (HfO₂). The interlayer insulating layer 115 may be a single layer or multi-layer including the above-described inorganic insulating material.

The first source electrode S1 and the first drain electrode D1 may be arranged on the interlayer insulating layer 115. The first source electrode S1 and the first drain electrode D1 may include a conductive material such as Mo, Al, Cu, Ti, or the like, and may have a multi-layered or single layer including the above-described materials. In an example, the first source electrode S1 and the first drain electrode D1 may have a multi-layered structure of Ti/Al/Ti.

A first organic insulating layer OL1 may be arranged on the interlayer insulating layer 115 to at least partially cover the first source electrode S1 and the first drain electrode D1. First connection electrodes CM1 and CM1′, which are connected to the pixel circuits PCm and PCc, respectively, may be arranged on the first organic insulating layer OL1. The first connection electrodes CM1 and CM1′ may include a conductive material such as Mo, Al, Cu, Ti, or the like, and may have a multi-layered or single layer including the above-described materials.

A second organic insulating layer OL2 for at least partially covering the first connection electrodes CM1 and CM1′ may be arranged on the first organic insulating layer OL1. The first connection wirings CWL1 and the second connection electrode CM2 may be arranged on the second organic insulating layer OL2. The first connection wirings CWL1 may be connected to the first connection electrode CM1′ connected to the corner pixel circuit PCc, and the second connection electrode CM2 may be connected to the first connection electrode CM1 connected to the main pixel circuit PCm.

The first connection wirings CWL1 and the second connection electrode CM2 may include a conductive material such as Mo, Al, Cu, Ti, or the like, and may have a multi-layered or single layer including the above-described materials. Alternatively, the first connection wirings CWL1 and the second connection electrode CM2 may include transparent conductive materials. For example, the first connection wirings CWL1 and the second connection electrode CM2 may include transparent conductive oxides (TCO). The first connection wirings CWL1 and the second connection electrode CM2 may include conductive oxide such as indium tin oxide (ITO), indium zinc oxide (IZO), zinc oxide (ZnO), indium oxide (In₂O₃), indium gallium oxide (IGO) or aluminum zinc oxide (AZO).

A third organic insulating layer OL3 for at least partially covering the first connection wirings CWL1 may be arranged on the second organic insulating layer OL2. Second connection wirings CWL2 may be arranged on the third organic insulating layer OL3. A (2-1)-th connection wiring CWL2-1 of the second connection wirings CWL2 may be connected to a (1-1)-th connection wiring CWL1-1 that is one of the first connection wirings CWL1 through a contact hole CNT1 passing through a third organic insulating layer OL3.

The second connection wirings CWL2 may include a conductive material such as Mo, Al, Cu, Ti, or the like, and may have a multi-layered or single layer including the above-described materials. Alternatively, the second connection wirings CWL2 may include a transparent conductive material. For example, the second connection wirings CWL2 may include transparent conductive oxides (TCO). The second connection wirings CWL2 may include conductive oxide such as indium tin oxide (ITO), indium zinc oxide (IZO), zinc oxide (ZnO), indium oxide (In₂O₃), indium gallium oxide (IGO) or aluminum zinc oxide (AZO).

At least one of the first connection wirings CWL1 and the second connection wirings CWL2 may extend from the first corner display area CDA1 to the second corner display area CDA2. Thus, at least one of the first connection wirings CWL1 and the second connection wirings CWL2 may overlap the driving circuit SDRV1.

A fourth organic insulating layer OL4 for at least partially covering the second connection wirings CWL2 may be arranged on the third organic insulating layer OL3. The fourth organic insulating layer OL4 may have a flat top surface so that the first pixel electrode 210 and the second pixel electrode 212 to be disposed on the fourth organic insulating layer OL4 may be flatly formed.

The first organic insulating layer OL1, the second organic insulating layer OL2, the third organic insulating layer OL3, and the fourth organic insulating layer OL4 may include benzocyclobutene (BCB), polyimide, hexamethyldisiloxane (HMDSO), polymethylmethacrylate (PMMA), a general-purpose polymer such as polystyrene (PS), a polymer derivative having a phenolic group, an acrylic polymer, an alkene polymer, an aryl ether-based polymer, an amide-based polymer, a fluorine-based polymer, a p-xylene-based polymer, or a vinyl alcohol-based polymer. There may be various modifications in which the first organic insulating layer OL1, the second organic insulating layer OL2, the third organic insulating layer OL3 and the fourth organic insulating layer OL4 may include the same material or different materials.

Light-emitting elements EDm, EDc1, and EDc2 may be arranged on the fourth organic insulating layer OL4. The main light-emitting element EDm may include a first pixel electrode 210, a first light-emitting layer 220, and an opposite electrode 230. A first corner light-emitting element EDc1 may include a second pixel electrode 212, a second light-emitting layer 222, and an opposite electrode 230, and a second corner light-emitting element EDc2 may include the second pixel electrode 212, a third light-emitting layer 223, and the opposite electrode 230. The first corner light-emitting element EDc1 and the second corner light-emitting element EDc2 may share the second pixel electrode 212.

The first pixel electrode 210 and the second pixel electrode 212 may include conductive oxide such as indium tin oxide (ITO), indium zinc oxide (IZO), zinc oxide (ZnO), indium oxide (In₂O₃), indium gallium oxide (IGO) or aluminum zinc oxide (AZO). The first pixel electrode 210 and the second pixel electrode 212 may include a reflective layer including Ag, Mg, Al, Pt, Pd, Au, Ni, Nd, Ir, Cr, or a compound thereof. For example, the first pixel electrode 210 and the second pixel electrode 212 may have a structure with layers formed of ITO, IZO, ZnO or In₂O₃ on/under the above-described reflective layer. In this case, the first pixel electrode 210 and the second pixel electrode 212 may have a stack structure of ITO/Ag/ITO.

A pixel-defining layer 119 may be arranged on the fourth organic insulating layer OL4 and may define a light-emitting area of the light-emitting elements EDm, EDc1, and EDc2. The pixel-defining layer 119 may cover the edge of the first pixel electrode 210 and may include a first opening OP1 for exposing the central portion of the first pixel electrode 210. The size and shape of the light-emitting area of the main light-emitting element EDm may be defined by the first opening OP1.

The pixel-defining layer 119 may cover the edge of the second pixel electrode 212 and may include a second opening OP2 and a third opening OP3 for exposing two areas of the central portion of the second pixel electrode 212. The second opening OP2 may define a light-emitting area of the first corner light-emitting element EDc1, and the third opening OP3 may define a light-emitting area of the second corner light-emitting element EDc2. In some embodiments, the size and shape of the second opening OP2 and the third opening OP3 may be the same.

The pixel-defining layer 119 may increase a distance between the edge of the pixel electrodes 210 and 212 and the opposite electrode 230 located on the pixel electrodes 210 and 212, thereby preventing an arc etc. from occurring in the edge of the pixel electrodes 210 and 212. The pixel-defining layer 119 may be formed of an organic insulating material, such as polyimide, polyamide, acrylic resin, BCB, HMDSO, and phenol resin, by using a method such as spin coating or the like.

A first light-emitting layer 220, a second light-emitting layer 222, and a third light-emitting layer 223 may be arranged inside the first opening OP1, the second opening OP2, and the third opening OP3 of the pixel-defining layer 119, respectively. The first light-emitting layer 220, the second light-emitting layer 222, and the third light-emitting layer 223 may include a polymer material or a small molecular (low-molecular weight) material, and may emit red, green, blue or white light. In an embodiment, the second light-emitting layer 222 and the third light-emitting layer 223 may include the same material and may emit light of the same color.

An organic functional layer (not shown) may be arranged on or under the first light-emitting layer 220, the second light-emitting layer 222, and the third light-emitting layer 223. The organic functional layer of the first light-emitting layer 220, the second light-emitting layer 222, and the third light-emitting layer 223 may include a hole injection layer (HIL), a hole transport layer (HTL), an electron transport layer (ETL) or an electron injection layer (EIL). The organic functional layer may be integrally formed to correspond to light-emitting elements included in the front display area FDA and the corner display area CDA.

The opposite electrode 230 may be arranged on the first light-emitting layer 220, the second light-emitting layer 222, and the third light-emitting layer 223. The opposite electrode 230 may include a conductive material having a low work function. For example, the opposite electrode 230 may include a (semi-)transparent layer including Ag, Mg, Al, Pt, Pd, Au, Ni, Nd, Ir, Cr, lithium (Li), Ca or an alloy thereof. Alternatively, the opposite electrode 230 may further include a layer including such as ITO, IZO, ZnO or In₂O₃ on the (semi-)transparent layer including the above-described material. The opposite electrode 230 may be integrally formed to correspond to the light-emitting elements EDm, EDc1, and EDc2 included in the front display area FDA and the corner display area CDA.

An upper layer 250 including an organic material may be formed on the opposite electrode 230. The upper layer 250 may be a layer provided to protect the opposite electrode 230 and to enhance optical extraction efficiency. The upper layer 250 may include an organic material having a higher refractive index than that of the opposite electrode 230. Alternatively, the upper layer 250 may be provided by stacking layers having different refractive indexes. For example, the upper layer 250 may be provided by stacking a high refractive index layer/a low refractive index layer/a high refractive index layer. In this case, the refractive index of the high refractive index layer may be 1.7 or more, and the refractive index of the low refractive index layer may be 1.3 or less.

The upper layer 250 may further include lithium fluoride (LiF). Alternatively, the upper layer 250 may further include an inorganic insulating material such as silicon oxide (SiO₂), silicon nitride (SiNx).

In the present embodiment, the corner pixel circuit PCc may be arranged in the first corner display area CDA1, and one corner pixel circuit PCc and at least two corner light-emitting elements EDc1 and EDc2 may be connected to each other. For example, one corner pixel circuit PCc may be connected to the first corner light-emitting element EDc1 and the second corner light-emitting element EDc2. In the drawings, one corner pixel circuit PCc and two corner light-emitting elements are connected to each other, but embodiments are not limited thereto. Various modifications in which one corner pixel circuit PCc and three to four corner light-emitting elements may be connected to each other, are possible.

The corner pixel circuit PCc may be connected to the corner light-emitting elements EDc1 and EDc2 via the connection wiring CWL that extends from the first corner display area CDA1 to the second corner display area CDA2. The connection wiring CWL may include a first connection wiring CWL1 disposed on the second organic insulating layer OL2 and a second connection wiring CWL2 disposed on the third organic insulating layer OL3.

A (2-1)-th connection wiring CWL2-1 of the second connection wirings CWL2 may be connected to a (1-1)-th connection wiring CWL1-1 of the first connection wirings CWL1 through a contact hole CNT1 passing through a third organic insulating layer OL3. The (1-1)-th connection wiring CWL1-1 may be connected to the first connection electrode CM1′ connected to the corner pixel circuit PCc via a contact hole, and the (2-1)-th connection wiring CWL2-1 may be connected to the second pixel electrode 212 via a contact hole so that the corner pixel circuit PCc may be connected to the corner light-emitting elements EDc1 and EDc2.

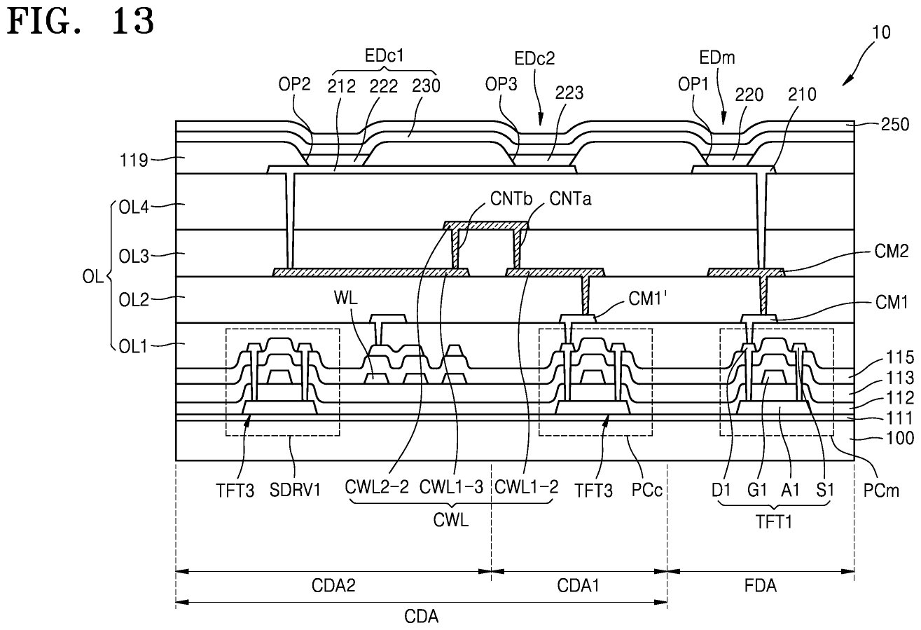

FIGS. 13 through 15 are cross-sectional views schematically illustrating a portion of a display panel 10 according to embodiments. In FIGS. 13 through 15, the same reference numerals as those of FIG. 12 represent the same elements, and thus, a redundant description thereof is omitted.

Referring to FIG. 13, the corner pixel circuit PCc may be connected to the corner light-emitting elements EDc1 and EDc2 via the connection wiring CWL that extends from the first corner display area CDA1 to the second corner display area CDA2.

The connection wiring CWL may include a (1-2)-th connection wiring CWL1-2 disposed on the second organic insulating layer OL2, a (1-3)-th connection wiring CWL1-3 disposed on the second organic insulating layer OL2, and a (2-2)-th connection wiring CWL2-2 disposed on the third organic insulating layer OL3. The (1-2)-th connection wiring CWL1-2 and the (1-3)-th connection wiring CWL1-3 may be arranged on the second organic insulating layer OL2 and may be spaced apart from each other. The (2-2)-th connection wiring CWL2-2 may be connected to the (1-2)-th connection wiring CWL1-2 via a first contact hole CNTa passing through the third organic insulating layer OL3 and may be connected to the (1-3)-th connection wiring CWL1-3 via a second contact hole CNTb. The (1-2)-th connection wiring CWL1-2 may be connected to the first connection electrode CM1′ connected to the corner pixel circuit PCc via a contact hole, and the (1-3)-th connection wiring CWL1-3 may be connected to the second pixel electrode 212 via a contact hole so that the corner pixel circuit PCc may be connected to the corner light-emitting elements EDc1 and EDc2.

As the connection wiring CWL includes the (1-2)-th connection wiring CWL1-2, the (1-3)-th connection wiring CWL1-3 and the (2-2)-th connection wiring CWL2-2, a degree of freedom when the connection wirings CWL are arranged may be increased.

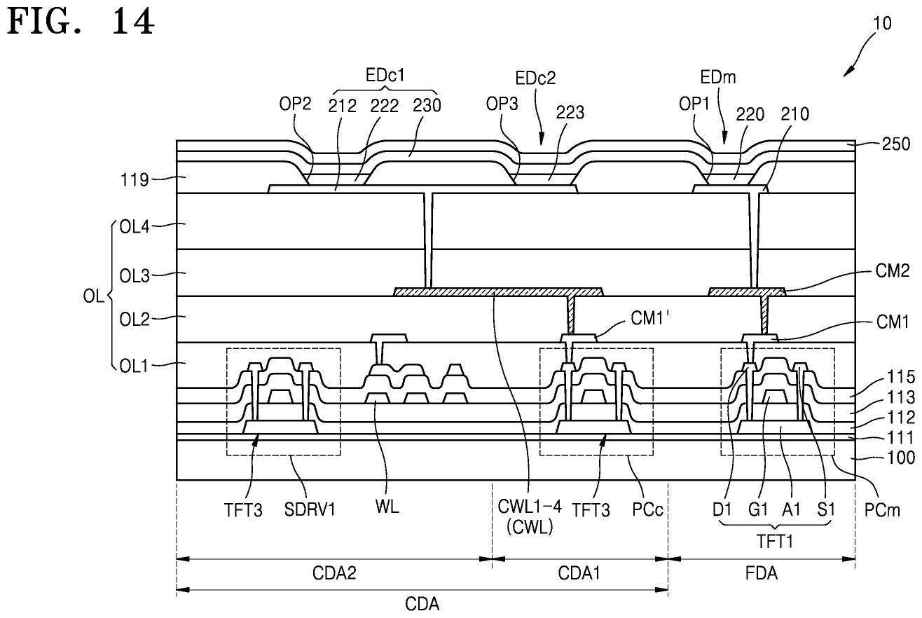

Referring to FIG. 14, the corner pixel circuit PCc may be connected to the corner light-emitting elements EDc1 and EDc2 via the connection wiring CWL that extends from the first corner display area CDA1 to the second corner display area CDA2.

The connection wiring CWL may include a (1-4)-th connection wiring CWL1-4 disposed on the second organic insulating layer OL2. The (1-4)-th connection wiring CWL1-4 may be one of the first connection wirings CWL1 disposed on the second organic insulating layer OL2. One end of the (1-4)-th connection wiring CWL1-4 may be connected to the first connection electrode CM1′ connected to the corner pixel circuit PCc via a contact hole, and the other end of (1-4)-th connection wiring CWL1-4 may be connected to the second pixel electrode 212 via a contact hole so that the corner pixel circuit PCc may be connected to the corner light-emitting elements EDc1 and EDc2. In the present embodiment, since the connection wirings CWL do not include a second connection wiring disposed on the third organic insulating layer OL3, the number of contact holes is reduced, and resistance due to the contact hole may be reduced.

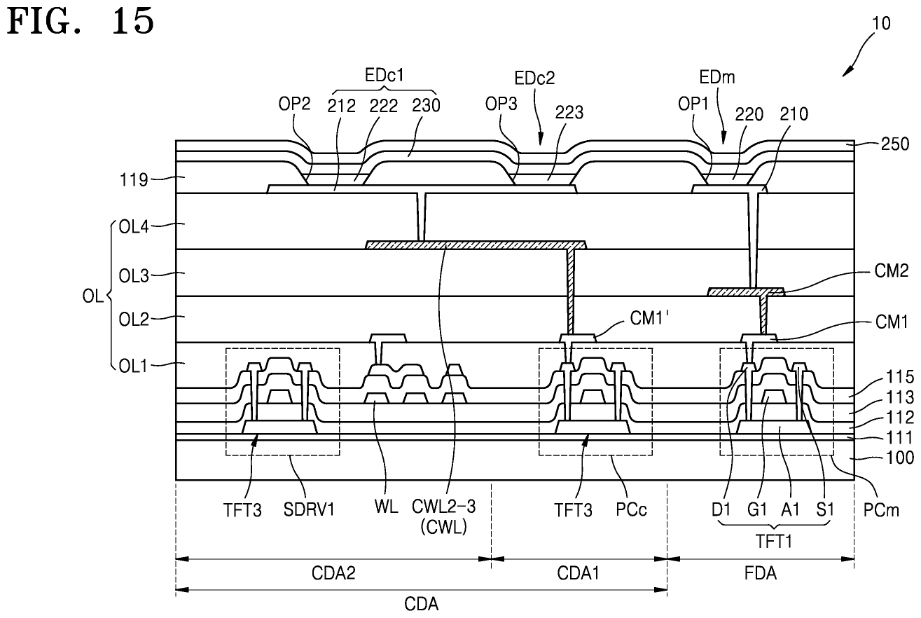

Referring to FIG. 15, the corner pixel circuit PCc may be connected to the corner light-emitting elements EDc1 and EDc2 via the connection wiring CWL that extends from the first corner display area CDA1 to the second corner display area CDA2.

The connection wiring CWL may include a (2-3)-th connection wiring CWL2-3. The (2-3)-th connection wiring CWL2-3 may be one of the second connection wirings CWL2 disposed on the third organic insulating layer OL3. One end of the (2-3)-th connection wiring CWL2-3 may be connected to the first connection electrode CM1′ connected to the corner pixel circuit PCc via a contact hole, and the other end of (2-3)-th connection wiring CWL2-3 may be connected to the second pixel electrode 212 via a contact hole so that the corner pixel circuit PCc may be connected to the corner light-emitting elements EDc1 and EDc2. In the present embodiment, since the connection wirings CWL do not include a first connection wiring disposed on the second organic insulating layer OL2, the number of contact holes is reduced, and resistance due to the contact hole may be reduced.

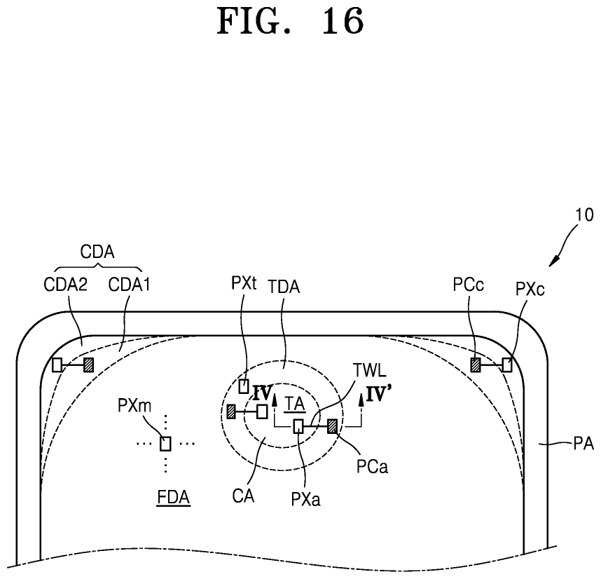

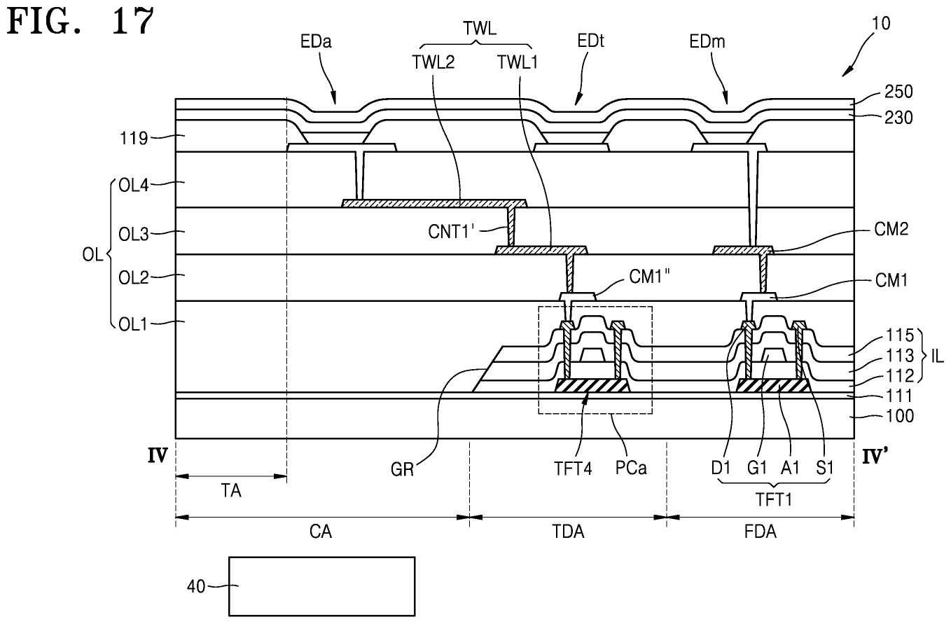

FIG. 16 is a schematic plan view illustrating an unfolded state of a portion of a display panel 10 according to an embodiment. FIG. 17 is a schematic cross-sectional view corresponding to a line IV-IV′ of FIG. 16. In FIG. 17, the same reference numerals as those of FIG. 12 represent the same elements, and thus, a redundant description thereof is omitted.

Referring to FIG. 16, the display panel 10 may further include a component area CA inside the front display area FDA, and a transition area TDA between the component area CA and the front display area FDA. The component area CA may be surrounded by the transition area TDA, and the transition area TDA may be surrounded by the front display area FDA. Pixels PXa and PXt may be arranged in the component area CA and the transition area TDA to display an image together with the front display area FDA or separately.

The planar shape of the component area CA may have various shapes such as polygonal shapes (for example, a rectangle shape, a star shape or a diamond shape), a circle shape, an oval shape, and the like. The position of the component area CA may also be variously modified. For example, as shown in FIG. 16, the component area CA may be at the center of the upper side of the front display area FDA or may be variously modified such as being disposed at the center of the right side or the center of the left side of the front display area FDA.

As shown in FIG. 17, a component 40 that is an electronic element may be disposed at a lower portion of the display panel 10 to correspond to the component area CA. The component 40 may be a camera using infrared rays or visible light and may include a capturing element. Alternatively, the component 40 may be a solar cell, a flash, an illuminance sensor, a proximity sensor, and an iris sensor. Alternatively, the component 40 may have a function of receiving sound. In order to minimize limitation of the function of the component 40, the component area CA may include a transmission area TA through which light or sound output from the component 40 or proceeding toward the component 40 from the outside may transmit. In the display panel 10 and the display apparatus including the same according to an embodiment, when light is transmitted through the component area CA, the light transmittance may be about 10% or more, more preferably 40% or more, 25% or more, 50% or more, 85% or more, or 90% or more.

A plurality of first auxiliary pixels PXa may be arranged in the component area CA. The plurality of first auxiliary pixels PXa may emit light to provide a certain image. The auxiliary pixel circuit PCa for driving the plurality of first auxiliary pixels PXa may not be arranged in the component area CA but may be arranged in the transition area TDA. That is, the auxiliary pixel circuit PCa may be disposed not to overlap the first auxiliary pixel PXa.

A plurality of second auxiliary pixels PXt may be arranged in the transition area TDA. The plurality of second auxiliary pixels PXt may emit light to provide a certain image. An auxiliary pixel circuit (not shown) for driving the plurality of second auxiliary pixels PXt may be disposed in the transition area TDA. That is, auxiliary pixel circuits for driving the first auxiliary pixels PXa and the second auxiliary pixels PXt may be arranged in the transition area TDA. In some embodiments, the first auxiliary pixels PXa and the second auxiliary pixels PXt may include copy pixels.

Referring to FIG. 17, a main light-emitting element EDm for implementing main pixels PXm (see FIG. 16) and a main pixel circuit PCm for driving the main light-emitting element EDm may be arranged in the front display area FDA. A first auxiliary light-emitting element EDa for implementing a first auxiliary pixel PXa (see FIG. 16) may be arranged in the component area CA, and the transmission area TA may be in the component area CA. A second auxiliary light-emitting element EDt for implementing a second auxiliary pixel PXt (see FIG. 16) may be arranged in the transition area TDA, and an auxiliary pixel circuit PCa for driving the first auxiliary light-emitting element EDa may be arranged in the transition area TDA. The first auxiliary light-emitting element EDa and the second auxiliary light-emitting element EDt may include organic light-emitting diodes.

The auxiliary pixel circuit PCa may include at least one thin film transistor TFT4 and may be connected to the first auxiliary light-emitting element EDa via a transparent connection wiring TWL. The transparent connection wiring TWL may extend from the transition area TDA to the component area CA. The transparent connection wiring TWL may be disposed in the transmission area TA. Since the transparent connection wiring TWL may include a transparent conductive material having high transmittance, even when the transparent connection wiring TWL is disposed in the transmission area TA, the transmittance of the transmission area TA may be secured.

The transparent connection wiring TWL may include a first transparent connection wiring TWL1 and a second transparent connection wiring TWL2, which are arranged in different layers. In this case, the first transparent connection wiring TWL1 may be disposed on a second organic insulating layer OL2, the first transparent connection wiring TWL1 being positioned in the same layer as the first connection wiring (see the first connection wiring CWL1 of FIG. 12). The first transparent connection wiring TWL1 may include the same material as the first connection wiring CWL1. The second transparent connection wiring TWL2 may be disposed on a third organic insulating layer OL3, the second transparent connection wiring TWL2 being positioned in the same layer as the second connection wiring (see the second connection wiring CWL2 of FIG. 12). The second transparent connection wiring TWL2 may include the same material as the second connection wiring CWL2.

The first transparent connection wiring TWL1 and the second transparent connection wiring TWL2 may include conductive oxide such as indium tin oxide (ITO), indium zinc oxide (IZO), zinc oxide (ZnO), indium oxide (In₂O₃), indium gallium oxide (IGO) or aluminum zinc oxide (AZO).

The inorganic insulating layer IL disposed on the substrate 100 may include a groove GR or a hole corresponding to the component area CA. For example, when the buffer layer 111, the first gate insulating layer 112, the second gate insulating layer 113, and the interlayer insulating layer 115 are collectively referred to as an inorganic insulating layer IL, the inorganic insulating layer IL may have a groove GR or a hole corresponding to the component area CA. The groove GR or the hole may expose a portion of the upper surface of the buffer layer 111 or the substrate 100. An opening of the first gate insulating layer 112 formed to correspond to the component area CA, an opening of the second gate insulating layer 113, and an opening of the interlayer insulating layer 115 may overlap each other. The openings may be formed through separate processes or may be simultaneously formed through the same process. When the openings are formed in a separate process, the inner surface of the groove GR may not be smooth and may have a step like a step shape. Since the groove GR is formed in the inorganic insulating layer IL, the light transmittance of the component area CA may be improved.

As described above, the display panel and the display apparatus according to the present embodiments may have a corner display area so that an area in which an image is displayed can be extended.

It should be understood that embodiments described herein should be considered in a descriptive sense only and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope as defined by the attached claims.

What is claimed is:

1. A display panel, wherein the display panel comprises:
a substrate comprising a front display area, a first corner display area extending from a corner of the front display area, and a second corner display area extending from the first corner display area;
a plurality of corner light-emitting elements arranged in the second corner display area;
a plurality of pixel circuits arranged in the first corner display area;
driving circuits arranged in the second corner display area and configured to provide driving signals to the plurality of pixel circuits; and
a plurality of connection wirings connecting the plurality of pixel circuits and the plurality of corner light-emitting elements to each other and extending from the first corner display area to the second corner display area,
wherein the plurality of connection wirings comprise first connection wirings disposed on a first layer and second connection wirings disposed on a second layer, and one of the plurality of pixel circuits is connected to at least two of the plurality of corner light-emitting elements.

2. The display panel of claim 1, wherein the plurality of corner light-emitting elements comprise a plurality of first light-emitting elements configured to emit light of a first color, a plurality of second light-emitting elements configured to emit light of a second color, and a plurality of third light-emitting elements configured to emit light of a third color, and
at least two of the plurality of second light-emitting elements share a pixel electrode of the at least two of the plurality of second light-emitting elements, and at least two of the plurality of third light-emitting elements share a pixel electrode of the at least two of the plurality of third light-emitting elements.

3. The display panel of claim 2, wherein at least two of the first light-emitting elements are connected to each other by a bridge wiring disposed on the first layer or the second layer.

4. The display panel of claim 1, wherein, in one of the plurality of connection wirings, a (1-1)-th connection wiring disposed on the first layer and a (2-1)-th connection wiring disposed on the second layer are connected to each other via a contact hole.

5. The display panel of claim 1, wherein one of the plurality of connection wirings comprises a (1-2)-th connection wiring and a (1-3)-th connection wiring, which are disposed on the first layer, and a (2-2)-th connection wiring disposed on the second layer, and
the (2-2)-th connection wiring is connected to the (1-2)-th connection wiring via a first contact hole and is connected to the (1-3)-th connection wiring via a second contact hole.

6. The display panel of claim 1, wherein one of the plurality of connection wirings includes a (1-4)-th connection wiring disposed on the first layer, and one end of the (1-4)-th connection wiring is connected to one of the plurality of pixel circuits, and the other end of the (1-4)-th connection wiring is connected to a pixel electrode of one of the plurality of corner light-emitting elements via a contact hole.

7. The display panel of claim 1, wherein one of the plurality of connection wirings includes a (2-3)-th connection wiring disposed on the second layer, and one end of the (2-3)-th connection wiring is connected to one of the plurality of pixel circuits, and the other end of the (2-3)-th connection wiring is connected to a pixel electrode of one of the plurality of corner light-emitting elements via a contact hole.

8. The display panel of claim 1, wherein the first connection wirings and the second connection wirings comprise transparent conductive materials.

9. The display panel of claim 1, wherein the substrate further comprises a component area inside the front display area and including a transmission area, and a transition area between the component area and the front display area, and
the display panel further comprises:
auxiliary light-emitting elements arranged in the component area;
auxiliary pixel circuits arranged in the transition area and configured to drive the auxiliary light-emitting elements; and
a plurality of transparent connection wirings connecting the auxiliary pixel circuits and the auxiliary light-emitting elements to each other, wherein the plurality of transparent connection wirings comprise a first transparent connection wiring disposed on the first layer and a second transparent connection wiring disposed on the second layer.

10. The display panel of claim 9, wherein the display panel further comprises an inorganic insulating layer disposed on the substrate, wherein the inorganic insulating layer has a groove corresponding to the component area.

11. A display apparatus, wherein the display apparatus comprises:
a cover window comprising a planar portion and a curved portion bent at a corner of the planar portion; and
a display panel disposed on one side of the cover window and comprising a front display area overlapping the planar portion and a first corner display area and a second corner display area, which overlap the curved portion, wherein the display panel further comprises:
a plurality of pixel circuits arranged in the first corner display area;
a plurality of corner light-emitting elements arranged in the second corner display area; and
a plurality of connection wirings connecting the plurality of pixel circuits and the plurality of corner light-emitting elements to each other and extending from the first corner display area to the second corner display area, wherein the plurality of connection wirings comprise first connection wirings disposed on a first layer and second connection wirings disposed on a second layer, and one of the plurality of pixel circuits is connected to at least two of the plurality of corner light-emitting elements.

12. The display apparatus of claim 11, wherein at least two of the plurality of corner light-emitting elements share a pixel electrode of the at least two of the plurality of corner light-emitting elements.

13. The display apparatus of claim 11, wherein, in one of the plurality of connection wirings, a (1-1)-th connection wiring disposed on the first layer and a (2-1)-th connection wiring disposed on the second layer are connected to each other via a contact hole.

14. The display apparatus of claim 11, wherein one of the plurality of connection wirings comprises a (1-2)-th connection wiring and a (1-3)-th connection wiring, which are disposed on the first layer, and a (2-2)-th connection wiring disposed on the second layer, and
the (2-2)-th connection wiring is connected to the (1-2)-th connection wiring via a first contact hole and is connected to the (1-3)-th connection wiring via a second contact hole.

15. The display apparatus of claim 11, wherein one of the plurality of connection wirings includes a (1-4)-th connection wiring disposed on the first layer, and one end of the (1-4)-th connection wiring is connected to one of the plurality of pixel circuits, and the other end of the (1-4)-th connection wiring is connected to a pixel electrode of one of the plurality of corner light-emitting elements via a contact hole.

16. The display apparatus of claim 11, wherein one of the plurality of connection wirings includes a (2-3)-th connection wiring disposed on the second layer, and one end of the (2-3)-th connection wiring is connected to one of the plurality of pixel circuits, and the other end of the (2-3)-th connection wiring is connected to a pixel electrode of one of the plurality of corner light-emitting elements via a contact hole.

17. The display apparatus of claim 11, wherein the first connection wirings and the second connection wirings comprise transparent conductive materials.

18. The display apparatus of claim 11, wherein a resolution of the front display area is the same as a resolution of the plurality of corner light-emitting elements.

19. The display apparatus of claim 11, wherein the display panel further comprises a component area inside the front display area and including a transmission area; and a transition area between the component area and the front display area, and
the display apparatus further comprises:
auxiliary light-emitting elements arranged in the component area;
auxiliary pixel circuits arranged in the transition area and configured to drive the auxiliary light-emitting elements; and
a plurality of transparent connection wirings connecting the auxiliary pixel circuits and the auxiliary light-emitting elements to each other, wherein the plurality of transparent connection wirings comprise a first transparent connection wiring disposed on the first layer and a second transparent connection wiring disposed on the second layer.

20. The display apparatus of claim 11, wherein the display panel further comprises a component area inside the front display area, and
a component corresponding to the component area is further disposed at a lower portion of the display panel.
